(19) United States
(12) Patent Application Publication
(10) Pub. No.: US 2026/0025995 A1
(43) Pub. Date: Jan. 22, 2026

(54) MEMORY DEVICE INCLUDING WORD LINE CONTACT

(71) Applicant: SK hynix Inc., Gyeonggi-do (KR)

(72) Inventors: Won Jae CHOI, Gyeonggi-do (KR); Jung Hoon HAM, Gyeonggi-do (KR)

(21) Appl. No.: 18/957,871

(22) Filed: Nov. 25, 2024

(30) Foreign Application Priority Data
Jul. 18, 2024 (KR) 10-2024-0095215

(51) Int. Cl. H10B 43/27; H10B 43/10; H10B 43/40

(52) U.S. Cl. CPC H10B 43/27; H10B 43/10; H10B 43/40

(57) ABSTRACT

According to embodiments of the present disclosure, a memory device may include a first substrate including a cell region and an extended region which extends from the cell region in a first direction; a stack structure including a plurality of interlayer insulating layers and a plurality of electrode layers which are alternately stacked on the first substrate, each of the plurality of electrode layers including a protrusion which protrudes in the extended region in a second direction that is perpendicular to the first direction and is parallel to an upper surface of the first substrate; and a word line contact disposed in the extended region and passing through the protrusion of each of the plurality of electrode layers in a vertical direction.

### CROSS-REFERENCE TO RELATED APPLICATION

The present application claims priority under 35 U.S.C. § 119(a) to Korean Patent Application No. 10-2024-0095215 filed on Jul. 18, 2024, which is incorporated herein by reference in its entirety.

### BACKGROUND

### 1. Technical Field

Embodiments of the present disclosure relate to a memory device, and more particularly, to a memory device including a word line contact.

### 2. Related Art

A three-dimensional memory device having memory cells which are three-dimensionally arranged has been proposed. The three-dimensional memory device has advantages in that a larger capacity may be realized within the same area by stacking memory cells in a vertical direction to increase the number of stacks so as to highly integrate memory cells, thereby providing high performance and excellent power efficiency.

### SUMMARY

Various embodiments of the present disclosure are directed to providing a memory device with a simplified manufacturing process.

In an embodiment of the present disclosure, a memory device may include a first substrate including a cell region and an extended region which extends from the cell region in a first direction; a stack structure including a plurality of interlayer insulating layers and a plurality of electrode layers which are alternately stacked on the first substrate, each of the plurality of electrode layers including a protrusion which protrudes in the extended region in a second direction that is perpendicular to the first direction and is parallel to an upper surface of the first substrate; and a word line contact disposed in the extended region and passing through the protrusion of each of the plurality of electrode layers in a vertical direction.

In an embodiment of the present disclosure, a memory device may include a first substrate; a stack structure including a plurality of interlayer insulating layers and a plurality of electrode layers which are alternately stacked on the first substrate, each of the plurality of electrode layers including a protrusion which does not overlap the other electrode layers in a vertical direction and protrudes in a direction parallel to an upper surface of the first substrate; and a word line contact passing through the protrusion of each of the plurality of electrode layers in the vertical direction.

In an embodiment of the present disclosure, a memory device may include a substrate including a cell region and an extended region which extends from the cell region in a first direction; a stack structure including a plurality of interlayer insulating layers and a plurality of electrode layers which are alternately stacked on the substrate; a cell plug passing through the stack structure in a vertical direction in the cell region; and a word line contact passing through one electrode layer among the plurality of electrode layers in the vertical direction in the extended region.

According to the embodiments of the present disclosure, the manufacturing process of a memory device may be simplified.

### BRIEF DESCRIPTION OF THE DRAWINGS

FIG. 1 is a block diagram of a memory device according to embodiments of the present disclosure.

FIG. 2 is an equivalent circuit diagram of a memory cell array illustrated in FIG. 1.

FIG. 3 is a view illustrating a planar structure of the memory device according to the embodiments of the present disclosure.

FIG. 4 is a view illustrating a cross-sectional structure of a part indicated by the line I-I′ of FIG. 3.

FIG. 5 is a perspective view of the memory device according to the embodiments of the present disclosure.

FIG. 6 is a view illustrating cross-sectional and planar structures of a word line contact and a cell plug according to the embodiments of the present disclosure.

FIG. 7 is a view illustrating another cross-sectional structure of the memory device according to the embodiments of the present disclosure.

FIG. 8 is a view illustrating still another cross-sectional structure of the memory device according to the embodiments of the present disclosure.

FIG. 9 is a view illustrating a cross-sectional structure of a memory device different from the memory device according to the embodiments of the present disclosure.

### DETAILED DESCRIPTION

Embodiments of the present disclosure are described detail with reference to the accompanying drawings. Specific structural or functional descriptions of the embodiments are provided as examples to describe concepts that are disclosed in the present disclosure. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

In the accompanying drawings, two directions that are parallel to the upper surface of a substrate are defined as a first direction FD and a second direction SD, respectively, and a direction that vertically protrudes from the upper surface of the substrate is defined as a third direction VD. The first direction FD and the second direction SD may be substantially perpendicular to each other. The third direction VD is a direction that is perpendicular to the first direction FD and the second direction SD. In the following description, the term ‘vertical’ or ‘vertical direction’ will be used as substantially the same meaning as the third direction VD. In the drawings, a direction indicated by an arrow and a direction opposite thereto represent the same direction.

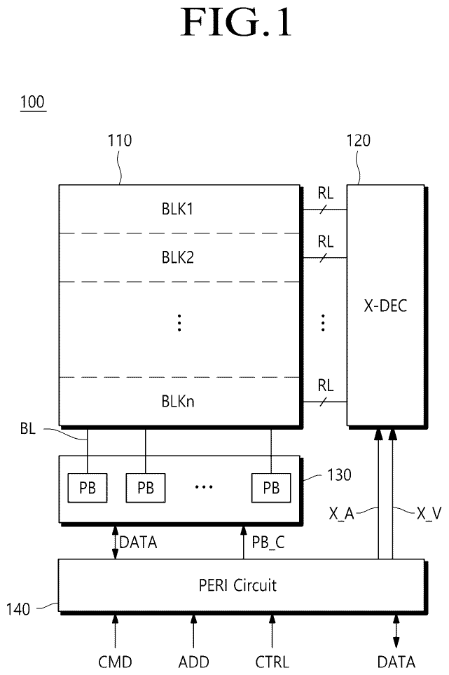

FIG. 1 is a block diagram of a memory device 100 according to embodiments of the present disclosure.

Referring to FIG. 1, the memory device 100 may include a memory cell array 110, a row decoder (X-DEC) 120, a page buffer circuit 130, and a peripheral circuit (PERI circuit) 140.

The memory cell array 110 may include a plurality of memory blocks BLK1 to BLKn, where n is a natural number of 2 or more. Although not illustrated, each of the memory blocks BLK1 to BLKn may include a plurality of cell strings. Each of the cell strings may include at least one drain select transistor, a plurality of memory cells and at least one source select transistor which are connected in series. Each memory cell may be a volatile memory cell or may be a nonvolatile memory cell. While it is described below that the memory device 100 is a vertical NAND flash device, it is to be understood that the technical idea of the present disclosure is not limited thereto.

The row decoder 120 may be connected to the memory cell array 110 through row lines RL. The row lines RL may include at least one drain select line, a plurality of word lines and at least one source select line.

The row decoder 120 may select one among the memory blocks BLK1 to BLKn, in response to a row address X_A provided from the peripheral circuit 140. The row decoder 120 may transmit an operating voltage X_V provided from the peripheral circuit 140, to row lines RL connected to a memory block selected from among the memory blocks BLK1 to BLKn.

The memory cell array 110 may be connected to the page buffer circuit 130 through bit lines BL. The page buffer circuit 130 may include a plurality of page buffers PB which are connected to the bit lines BL, respectively. The page buffer circuit 130 may receive a page buffer control signal PB_C from the peripheral circuit 140, and may transmit and receive a data signal DATA to and from the peripheral circuit 140. The page buffer circuit 130 may control bit lines BL which are arranged in the memory cell array 110, in response to the page buffer control signal PB_C. For example, the page buffer circuit 130 may detect data, stored in memory cells of the memory cell array 110, by sensing the signals of bit lines BL of the memory cell array 110 in response to the page buffer control signal PB_C. Further, the page buffer circuit 130 may transmit the data signal DATA to the peripheral circuit 140 according to the detected data. The page buffer circuit 130 may apply signals to bit lines BL based on the data signal DATA received from the peripheral circuit 140, in response to the page buffer control signal PB_C, and accordingly, may write data to memory cells of the memory cell array 110. The page buffer circuit 130 may write or read data to or from memory cells which are connected to a word line activated by the row decoder 120.

The peripheral circuit 140 may receive a command signal CMD, an address signal ADD and a control signal CTRL from an external device outside the memory device 100. Further, the peripheral circuit 140 may transmit and receive data DATA to and from the external device. For example, the external device may be a memory controller. The peripheral circuit 140 may output signals for writing data to the memory cell array 110 or reading data from the memory cell array 110, for example, the row address X_A, the page buffer control signal PB_C, a source line discharge control signal (SLD_C) and so on, based on the command signal CMD, the address signal ADD and the control signal CTRL. The peripheral circuit 140 may generate various voltages including the operating voltage X_V, which are required in the memory device 100.

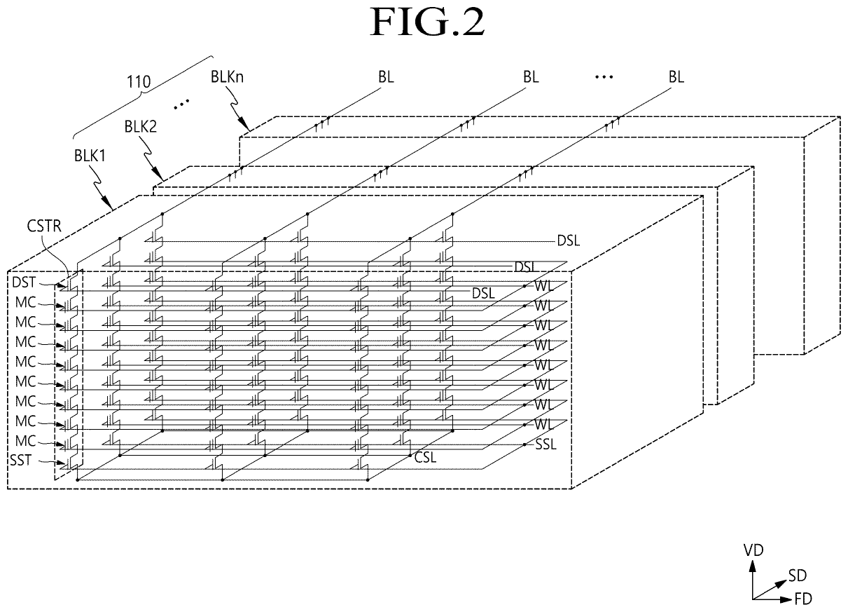

FIG. 2 is an equivalent circuit diagram of the memory cell array 110 illustrated in FIG. 1.

Referring to FIG. 2, each of the memory blocks BLK1 to BLKn may include a plurality of cell strings CSTR which are connected between a plurality of bit lines BL and a common source line CSL.

The bit lines BL may extend in the second direction SD, and may be arranged in the first direction FD. The plurality of cell strings CSTR may be connected in parallel to each of the bit lines BL. The cell strings CSTR may be connected in common to the common source line CSL. The plurality of cell strings CSTR may be disposed between the plurality of bit lines BL and the one common source line CSL.

Each of the cell strings CSTR may include a drain select transistor DST which is connected to a bit line BL, a source select transistor SST which is connected to the common source line CSL, and a plurality of memory cells MC which are connected between the drain select transistor DST and the source select transistor SST. The drain select transistor DST, the memory cells MC and the source select transistor SST may be connected in series in the vertical direction VD.

Drain select lines DSL, a plurality of word lines WL and a source select line SSL may be disposed between the bit lines BL and the common source line CSL in the third direction VD. Each of the drain select lines DSL may be connected to the gates of corresponding drain select transistors DST. Each of the word lines WL may be connected to the gates of corresponding memory cells MC. The source select line SSL may be connected to the gates of source select transistors SST. Memory cells MC which are connected in common to one word line WL may constitute one page.

The bit lines BL and the common source line CSL may be connected in common to the memory blocks BLK1 to BLKn. That is, the memory blocks BLK1 to BLKn may share the bit lines BL and the common source line CSL. The drain select lines DSL, the plurality of word lines WL and the source select line SSL may be provided to each of the memory blocks BLK1 to BLKn.

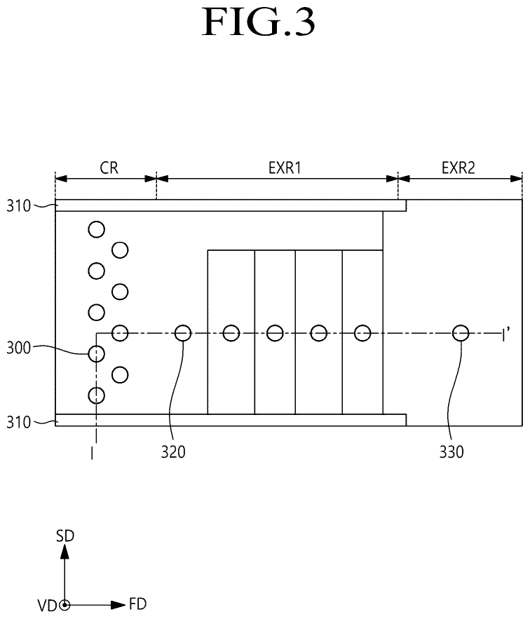

FIG. 3 is a view illustrating a planar structure of the memory device 100 according to the embodiments of the present disclosure.

Referring to FIG. 3, the memory device 100 includes a cell region CR, a first extended region EXR1 and a second extended region EXR2.

A plurality of cell plugs 300 are disposed in the cell region CR. The plurality of cell plugs 300 are arranged in the first direction FD and the second direction SD in the cell region CR. In the second direction SD, the plurality of cell plugs 300 are located between two adjacent slits 310. Each of the plurality of cell plugs 300 extends in the vertical direction VD.

The first extended region EXR1 as a region outside the cell region CR extends from the cell region CR in the first direction FD. The second extended region EXR2 extends from the first extended region EXR1 in the first direction FD.

A plurality of word line contacts 320 are disposed in the first extended region EXR1. The plurality of word line contacts 320 are arranged in the first direction FD. One word line contact 320 overlaps the other word line contacts 320 in the first direction FD. The plurality of word line contacts 320 extend in the vertical direction VD. In an embodiment, the length of one word line contact 320 in the vertical direction VD may be the same as the length of the other word line contacts 320 in the vertical direction VD.

At least one through contact 330 is disposed in the second extended region EXR2. The through contact 330 extends in the vertical direction VD. In an embodiment, the through contact 330 may electrically connect an external device (e.g., a memory controller) and the memory device 100.

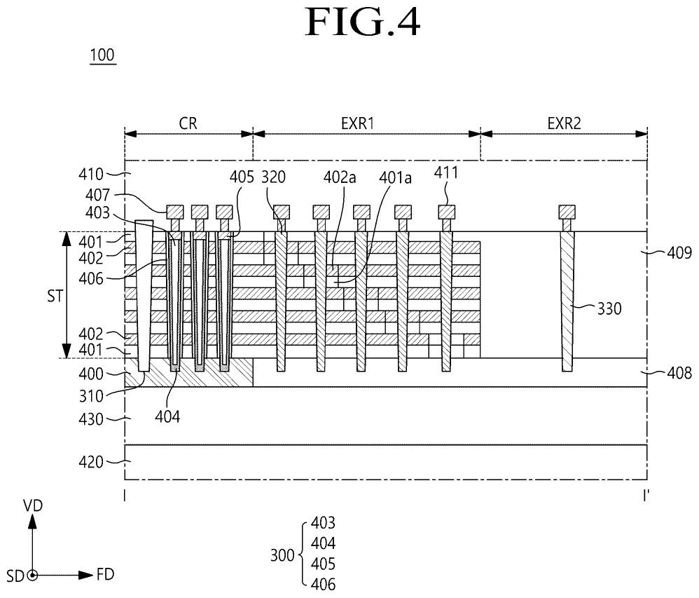

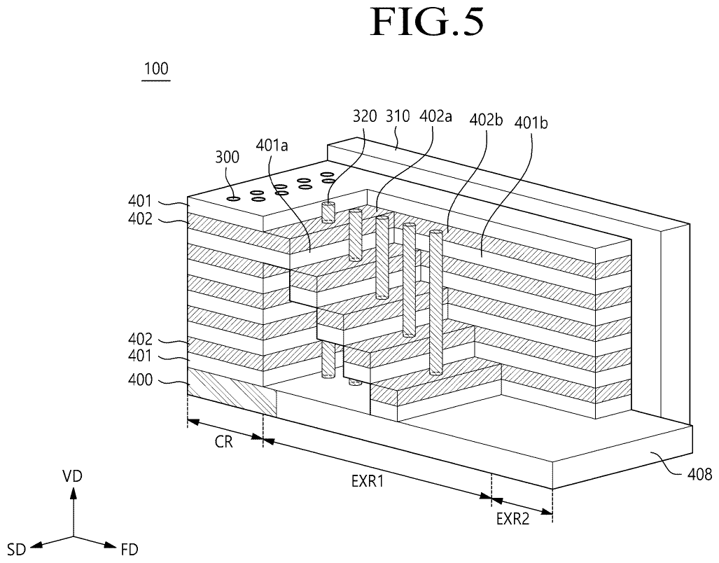

FIG. 4 is a view illustrating a cross-sectional structure of a part indicated by the line I-I′ of FIG. 3. FIG. 5 is an a perspective view of the memory device 100 according to the embodiments of the present disclosure.

Referring to FIGS. 4 and 5, the memory device 100 includes a first substrate 400, a stack structure ST, the slit 310, the cell plugs 300, first wirings 407, second wirings 411, the word line contacts 320, a third insulating layer 408, a fourth insulating layer 409, the through contact 330, a first insulating layer 410, a second substrate 420, and a second insulating layer 430.

In an embodiment, the first substrate 400 may include a semiconductor material such as polysilicon. The first substrate 400 may be connected to the common source line CSL. The first substrate 400 may also be referred to as a source plate. In an embodiment, the first substrate 400 may not overlap the plurality of word line contacts 320 in the vertical direction VD. The first substrate 400 might not extend to a region where the plurality of word line contacts 320 are disposed.

The stack structure ST is disposed on the first substrate 400. The stack structure ST includes a plurality of interlayer insulating layers 401 and a plurality of electrode layers 402 which are alternately stacked in the vertical direction VD. Each of the uppermost and lowermost layers of the stack structure ST may be an interlayer insulating layer 401.

The plurality of interlayer insulating layers 401 may include silicon oxide, silicon nitride, silicon oxynitride, silicon carbonitride (SiCN), silicon oxycarbonitride (SiOCN), low-k dielectric, high-k dielectric, or a combination thereof.

The plurality of electrode layers 402 may include Cu, Al, Ni, Co, Ru, W, WN, Ti, TIN, Ta, TaN, Sn, Pt, Au, Ag, or a combination thereof. The plurality of electrode layers 402 may include a plurality of word lines and a plurality of select lines. Memory cells MC may be formed at intersections of the cell plugs 300 and the plurality of word lines. Among the plurality of electrode layers 402, at least one adjacent to the first substrate 400 may correspond to a source select line. Among the plurality of electrode layers 402, at least one adjacent to drain pads 405 may correspond to a drain select line. A plurality of word lines may be disposed between at least one drain select line and at least one source select line among the plurality of electrode layers 402.

The stack structure ST is disposed on the first substrate 400 in the cell region CR and is disposed on the third insulating layer 408 in the first extended region EXR1. In an embodiment, the respective interlayer insulating layers 401 and the respective electrode layers 402 included in the stack structure ST may extend from the cell region CR to the same location in the first extended region EXR1 in the first direction FD.

Referring to FIGS. 3 and 5, each of interlayer insulating layers 401 except an uppermost interlayer insulating layer 401 among the interlayer insulating layers 401 includes an extension 401b which extends from the cell region CR to the first extended region EXR1 in the first direction FD and a protrusion 401a which protrudes from the extension 401b in the second direction SD.

Each of the electrode layers 402 includes an extension 402b which extends from the cell region CR to the first extended region EXR1 in the first direction FD and a protrusion 402a which protrudes from the extension 402b in the second direction SD.

In an embodiment, the length of the extension 401b of the interlayer insulating layer 401 in the first direction FD may be the same as the length of the extension 402b of the electrode layer 402 in the first direction FD. In addition, the length of the extension 401b of one interlayer insulating layer 401 in the first direction FD may be the same as the length of the extensions 401b of the other interlayer insulating layers 401 in the first direction FD. Similarly, the length of the extension 402b of one electrode layer 402 in the first direction FD may be the same as the length of the extensions 402b of the other electrode layers 402 in the first direction FD.

In an embodiment, the length of the protrusion 401a of an interlayer insulating layer 401 in the second direction SD may be the same as the length of the protrusion 402a of an electrode layer 402 in the second direction SD which overlaps the interlayer insulating layer 401 in the vertical direction VD. In addition, the length of the protrusion 401a of one interlayer insulating layer 401 in the second direction SD may be the same as the length of the protrusions 401a of the other interlayer insulating layers 401 in the second direction SD. Similarly, the length of the protrusion 402a of one electrode layer 402 in the second direction SD may be the same as the length of the protrusions 402a of the other electrode layers 402 in the second direction SD.

The protrusions 402a of the plurality of electrode layers 402 do not overlap each other in the vertical direction VD. Also, the protrusions 402a of the plurality of electrode layers 402 do not overlap each other in the second direction SD. The protrusions 402a of the plurality of electrode layers 402 may be spaced farther apart from the second insulating layer 430 of FIG. 4 in the vertical direction VD as the protrusions 402a approach the cell region CR in the first direction FD.

The slit 310 extends in the first direction FD and the vertical direction VD, and passes through the stack structure ST. The slit 310 may be disposed two-dimensionally on a plane including the first direction FD and the vertical direction VD. The slit 310 may include at least one of silicon oxide, silicon nitride and silicon oxynitride, but is not limited thereto. In an embodiment, the upper surface of the slit 310 may be located at a higher level in the vertical direction VD than the upper surface of the stack structure ST.

In the cell region CR, the plurality of cell plugs 300 pass through the stack structure ST in the vertical direction VD. The cell plugs 300 pass through all of the plurality of interlayer insulating layers 401 and the plurality of electrode layers 402 included in the stack structure ST. In an embodiment, the upper surfaces of the cell plugs 300 may be located at a higher level in the vertical direction VD than the upper surface of the uppermost layer of the stack structure ST. The lower surfaces of the cell plugs 300 are located at a lower level in the vertical direction VD than the lower surface of the lowermost layer of the stack structure ST. Namely, the cell plugs 300 extend into the first substrate 400.

Each cell plug 300 includes a core layer 403, a channel pattern 404, a drain pad 405 and an information storage structure 406. The core layer 403 may include silicon oxide, silicon nitride, silicon oxynitride, polysilicon, or a combination thereof. The channel pattern 404 surrounds the core layer 403. In the channel pattern 404, the channel region of a transistor included in a memory cell may be formed. The channel pattern 404 may include a semiconductor material such as polysilicon. The drain pad 405 is disposed on the core layer 403 and the channel pattern 404. The drain pad 405 may include a semiconductor material such as polysilicon.

The information storage structure 406 is disposed between the channel pattern 404 and the interlayer insulating layers 401 and between the channel pattern 404 and the electrode layers 402. The information storage structure 406 may include a tunnel layer, a charge trap layer and a blocking layer. The tunnel layer may be disposed on the channel pattern 404. The tunnel layer may include silicon oxide, silicon nitride, aluminum oxide (Al2O3), magnesium oxide (MgO) or zirconium oxide (ZrO2). The charge trap layer may be disposed on the tunnel layer. In an embodiment, the charge trap layer may include silicon nitride. The blocking layer may be disposed on the charge trap layer. In an embodiment, the blocking layer may include aluminum oxide (Al2O3). The outer side surface of the blocking layer may contact the interlayer insulating layers 401 and the electrode layers 402 of the stack structure ST.

Each of the plurality of cell plugs 300 is connected to the first wiring 407. In an embodiment, the first wiring 407 may be a bit line BL. The first wiring 407 may include a conductive material such as metal, metal oxide, metal nitride, metal silicide, polysilicon, conductive carbon or a combination thereof.

Each of the plurality of word line contacts 320 passes through the protrusion 402a of one electrode layer 402 and the protrusion 401a of one interlayer insulating layer 401. That is, each word line contact 320 does not pass through the other electrode layers 402 and the other interlayer insulating layers 401 except one electrode layer 402 and one interlayer insulating layer 401 through which the word line contact 320 passes.

In an embodiment, the upper surfaces of the plurality of word line contacts 320 may be located at a higher level in the vertical direction VD than the upper surface of the uppermost layer of the stack structure ST. In an embodiment, the upper surfaces of the plurality of word line contacts 320 may be located at the same level as the upper surfaces of the cell plugs 300.

In an embodiment, the lower surfaces of the plurality of word line contacts 320 may be located at a lower level in the vertical direction VD than the lower surface of the lowermost layer of the stack structure ST. In an embodiment, the lower surfaces of the plurality of word line contacts 320 may be located at the same level in the vertical direction VD as the lower surfaces of the cell plugs 300.

The side surface of each word line contact 320 contacts one electrode layer 402 and one interlayer insulating layer 401. Because one word line contact 320 contacts only one electrode layer 402, the one word line contact 320 is electrically connected to only the one electrode layer 402 through one protrusion 402a through which the one word line contact 320 passes.

The word line contacts 320 may extend into the third insulating layer 408 in the vertical direction VD. In an embodiment, a length by which each of the plurality of word line contacts 320 extends into the third insulating layer 408 in the vertical direction VD may be the same as a length by which each of the plurality of cell plugs 300 extends into the first substrate 400 in the vertical direction VD.

In an embodiment, the length of a word line contact 320 in the vertical direction VD which passes through one electrode layer 402 may be the same as the length of word line contacts 320 in the vertical direction VD which pass through the other electrode layers 402.

Each of the word line contacts 320 may include a conductive material such as metal, metal oxide, metal nitride, metal silicide, polysilicon, conductive carbon or a combination thereof.

Wirings or electrodes for transmitting various voltages and signals may be connected to the plurality of word line contacts 320, respectively. The wirings or electrodes may be connected to the word line contacts 320 through conductive contacts. The wirings or electrodes may receive operating voltages required for the operations of memory cells, from a peripheral circuit 140 of FIG. 1, and may transmit the operating voltages to the plurality of word line contacts 320. Each of the plurality of word line contacts 320 may transmit a received operating voltage to each electrode layer 402.

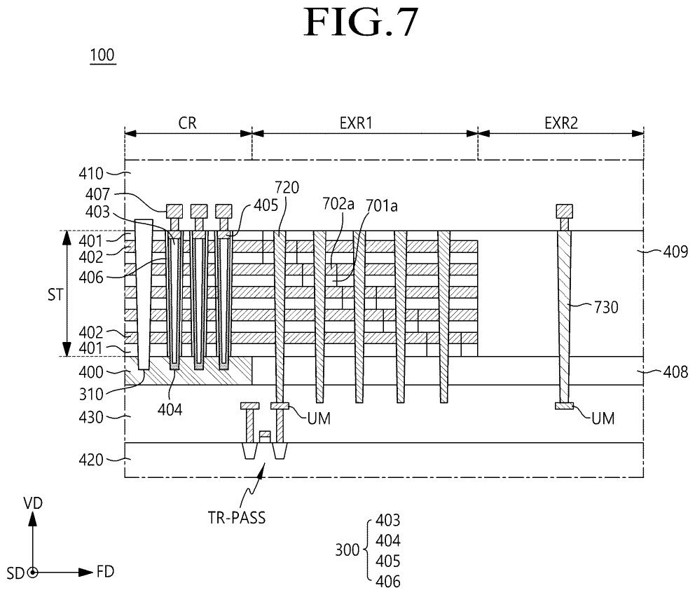

For example, the second wirings 411 may be connected to the plurality of word line contacts 320 through conductive contacts. Each of the plurality of word line contacts 320 may receive an operating voltage required for the operations of memory cells through a corresponding second wiring 411. Alternatively, in another embodiment, conductive contacts or wirings may be connected to the plurality of word line contacts 320, respectively, under the plurality of word line contacts 320. A structure in which wirings are disposed under the word line contacts 320 will be described later with reference to FIG. 7.

The third insulating layer 408 is disposed on the second insulating layer 430 in a region which overlaps the first substrate 400 in the first direction FD. The fourth insulating layer 409 is disposed on the plurality of interlayer insulating layers 401, the plurality of electrode layers 402 and the third insulating layer 408. The third insulating layer 408 and the fourth insulating layer 409 may include silicon oxide, silicon nitride, silicon oxynitride, silicon carbonitride (SiCN), silicon oxycarbonitride (SiOCN), low-k dielectric, high-k dielectric, or a combination thereof.

The first insulating layer 410 is disposed on the fourth insulating layer 409 and the stack structure ST. The first insulating layer 410 may include silicon oxide, silicon nitride, silicon oxynitride, silicon carbonitride (SiCN), silicon oxycarbonitride (SiOCN), low-k dielectric, high-k dielectric, or a combination thereof.

In an embodiment, the through contact 330 may extend into the third insulating layer 408 by passing through the fourth insulating layer 409 in the vertical direction VD in the second extended region EXR2. At least one conductive contact or wiring may be disposed on the through contact 330. The memory device 100 may be connected to an external device through at least one conductive contact which is disposed on the through contact 330. Although not illustrated, at least one conductive contact or wiring may also be disposed under the through contact 330. The at least one conductive contact or wiring disposed under the through contact 300 may be connected to a peripheral circuit 140 of FIG. 1. The through contact 330 may include a conductive material such as metal, metal oxide, metal nitride, metal silicide, polysilicon, conductive carbon or a combination thereof.

The second insulating layer 430 is disposed under the first substrate 400. The second insulating layer 430 may include silicon oxide, silicon nitride, silicon oxynitride, silicon carbonitride (SiCN), silicon oxycarbonitride (SiOCN), low-k dielectric, high-k dielectric, or a combination thereof.

The second substrate 420 is disposed under the second insulating layer 430. The second substrate 420 may include a semiconductor substrate such as a silicon wafer or an SOI (silicon on insulator) wafer. The second substrate 420 may include a III-V group semiconductor substrate, for example, a compound semiconductor substrate such as GaAs. The second substrate 420 may include monocrystalline silicon, polysilicon, amorphous silicon, monocrystalline silicon germanium, polycrystalline silicon germanium, carbon-doped silicon, or a combination thereof. Peripheral circuits including pass transistors may be disposed in the second substrate 420.

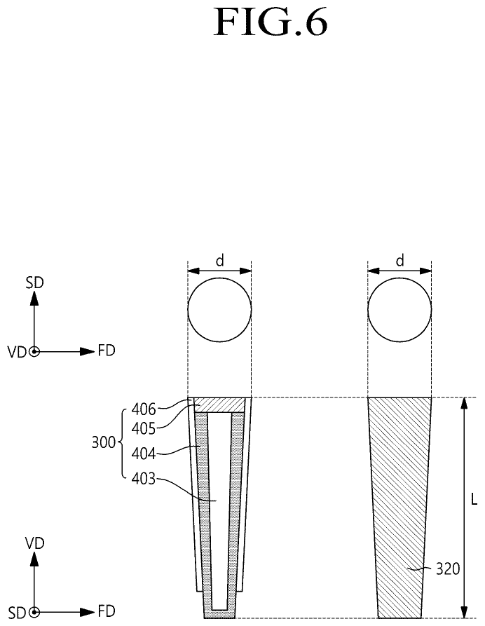

FIG. 6 is a view illustrating cross-sectional and planar structures of a word line contact and a cell plug according to the embodiments of the present disclosure.

Referring to FIG. 6, in an embodiment, a length L in the vertical direction VD of the cell plug 300 may be the same as a length L in the vertical direction VD of the word line contact 320. In addition, in an embodiment, a diameter d of the upper surface of the cell plug 300 may be the same as a diameter d of the upper surface of the word line contact 320.

Each of the processes for forming the word line contact 320 and the cell plug 300 includes a process of forming a through hole. In an embodiment, a process for forming a through hole to form the word line contact 320 may be the same as a process for forming a through hole to form the cell plug 300. For example, both the process for forming a through hole to form the word line contact 320 and the process for forming a through hole to form the cell plug 300 may include anisotropic etching through the stack structure ST. The anisotropic etching may be performed under the same condition in the course of forming each through hole. In an embodiment, the word line contact 320 may be formed in the same step as the cell plug 300.

FIG. 7 is a view illustrating another cross-sectional structure of the memory device 100 according to the embodiments of the present disclosure.

In the following, description of configurations of FIG. 7 which are substantially the same as those described above in the previous examples of FIG. 4 will be omitted.

Referring to FIG. 7, in the first extended region EXR1, each of a plurality of word line contacts 720 passes through a protrusion 701a of one interlayer insulating layer 401 and a protrusion 702a of one electrode layer 402. Each of the plurality of word line contacts 720 does not pass through the other interlayer insulating layers 401 and the other electrode layers 402 except one interlayer insulating layer 401 and one electrode layer 402 through which the corresponding word line contact 720 passes.

Each word line contact 720 extends into the second insulating layer 430 by passing through the fourth insulating layer 409 and the third insulating layer 408 in the vertical direction VD. In an embodiment, the lower surface of the word line contact 720 may be located at a lower level than the lower surface of the cell plug 300.

The length of the word line contact 720 in the vertical direction VD may be different from the length of the cell plug 300 in the vertical direction VD. In an embodiment, the length of the word line contact 720 in the vertical direction VD may be greater than the length of the cell plug 300 in the vertical direction VD.

In an embodiment, the word line contact 720 may pass through the third insulating layer 408, and thereby, may be connected to a bottom electrode UM which is disposed in the second insulating layer 430. The word line contact 720 may be connected through the bottom electrode UM to a first transistor TR-PASS which is disposed below the first substrate 400 and the third insulating layer 408. The first transistor TR-PASS may be a pass transistor which receives an operating voltage from a peripheral circuit 140 of FIG. 1 and transmits the operating voltage to a word line. Although FIG. 7 illustrates, for convenience, only the bottom electrode UM and the first transistor TR-PASS which are connected to one word line contact 320, each of the plurality of word line contacts 320 may be connected to a different bottom electrode UM and a different first transistor TR-PASS.

In an embodiment, in the second extended region EXR2, a through contact 730 may be connected to a bottom electrode UM by passing through the fourth insulating layer 409 and the third insulating layer 408. Although not illustrated, at least one conductive contact or electrode layer which is connected to the bottom electrode UM may be additionally disposed under the bottom electrode UM. The through contact 730 may be connected to a peripheral circuit 140 of FIG. 1 through the bottom electrode UM or the conductive contact or electrode layer which is additionally disposed.

In an embodiment, the word line contact 720 may be connected to the first transistor TR-PASS through the bottom electrode UM which is connected to the lower surface of the word line contact 720. Accordingly, a conductive contact or a wiring for connecting the word line contact 720 and the first transistor TR-PASS might not be disposed on the upper surface of the word line contact 720. Therefore, compared to a case where a conductive contact, a wiring or an electrode is disposed on the upper surface of the word line contact 720 to connect the word line contact 720 and the first transistor TR-PASS, a free space for wiring may be secured in the memory device 100, and the size of the memory device 100 may be reduced.

As described above, the second substrate 420, the second insulating layer 430, the first substrate 400 and the stack structure ST may be built up on a single wafer. After forming, in the second substrate 420, a plurality of first transistors TR-PASS, a block selection circuit, a page buffer circuit, a plurality of voltage switching circuits and various circuits corresponding to a peripheral circuit 140 of FIG. 1, a plurality of memory cells may be formed on the first substrate 400 and wirings for electrically connecting the plurality of memory cells and the circuits formed in the second substrate 420 may be formed. In this case, the memory device 100 may be defined as having a peripheral under cell (PUC) structure.

Alternatively, a plurality of pass transistors, a block selection circuit, a page buffer circuit, a plurality of voltage switching circuits and various circuits corresponding to a peripheral circuit, and a plurality of memory cells may be manufactured on different wafers, and then, the wafers may be bonded to each other to be integrated through a wafer bonding process. In this case, the memory device 100 may be defined as having a peripheral over cell (POC) structure.

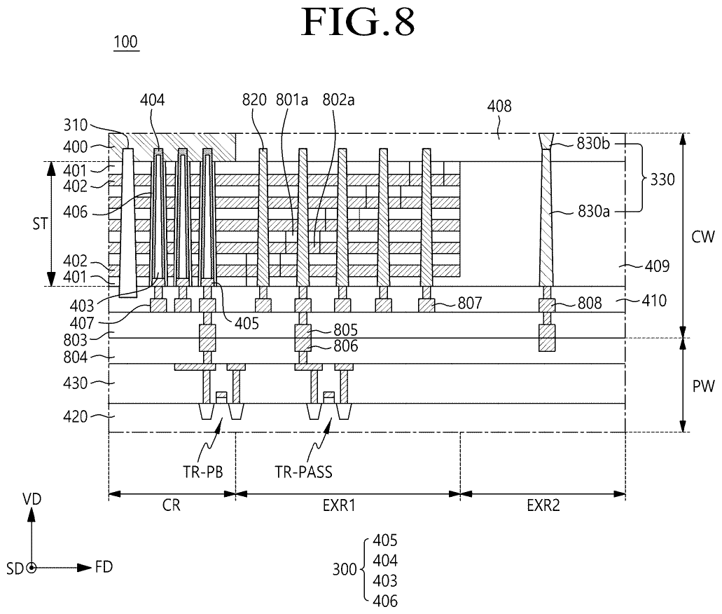

FIG. 8 is a view illustrating still another cross-sectional structure of the memory device 100 according to the embodiments of the present disclosure.

In the following, description of configurations FIG. 8 which are substantially the same as those in the previous examples of FIGS. 4 and 7 will be omitted.

Referring to FIG. 8, the memory device 100 includes a memory cell wafer CW and a peripheral wafer PW. The memory cell wafer CW and the peripheral wafer PW may be bonded to each other through a first bonding insulating layer 803, a second bonding insulating layer 804, first bonding pads 805 and second bonding pads 806.

The memory cell wafer CW includes a first substrate 400, a third insulating layer 408, a fourth insulating layer 409, a stack structure ST, a slit 310, a plurality of cell plugs 300, a plurality of word line contacts 820, a through contact 330, a plurality of wirings 407, 807 and 808, the first bonding insulating layer 803, and the plurality of first bonding pads 805.

The peripheral wafer PW includes a second substrate 420, a second insulating layer 430, a first transistor TR-PASS, a second transistor TR-PB, the second bonding insulating layer 804, and the plurality of second bonding pads 806.

The first transistor TR-PASS and the second transistor TR-PB are disposed in the second substrate 420 and the second insulating layer 430 of the peripheral wafer PW. The second transistor TR-PB may be a transistor which is included in a page buffer circuit 130 of FIG. 1.

The second bonding insulating layer 804 is disposed on the second insulating layer 430. The second bonding insulating layer 804 may include silicon oxide, silicon nitride, silicon oxynitride, silicon carbonitride (SiCN), silicon oxycarbonitride (SiOCN), low-k dielectric, high-k dielectric, or a combination thereof. The second bonding pads 806 are disposed in the second bonding insulating layer 804.

The first bonding insulating layer 803 is disposed on the second bonding insulating layer 804. The first bonding insulating layer 803 may include silicon oxide, silicon nitride, silicon oxynitride, silicon carbonitride (SiCN), silicon oxycarbonitride (SiOCN), low-k dielectric, high-k dielectric, or a combination thereof. The first bonding pads 805 are disposed in the first bonding insulating layer 803.

The first bonding pads 805 and the second bonding pads 806 overlap in the vertical direction VD. The lower surfaces of the first bonding pads 805 contact the upper surfaces of the second bonding pads 806. The lower surface of the first bonding insulating layer 803 contacts the upper surface of the second bonding insulating layer 804.

The plurality of wirings 407, 807 and 808 and the first insulating layer 410 are disposed on the first bonding insulating layer 803. Each of the plurality of wirings 407, 807 and 808 is electrically connected to a corresponding one of the plurality of first bonding pads 805. The first bonding pad 805 is electrically connected to the second bonding pad 806, and the second bonding pad 806 is connected to a corresponding first transistor TR-PASS. The plurality of wirings 407, 807 and 808 may include a conductive material such as metal, metal oxide, metal nitride, metal silicide, polysilicon, conductive carbon or a combination thereof.

The fourth insulating layer 409 and the stack structure ST are disposed on the first insulating layer 410. In the first extended region EXR1, the word line contacts 820 extend into the third insulating layer 408 by passing through the stack structure ST in the vertical direction VD. One word line contact 820 passes through a protrusion 802a of one electrode layer 402 and a protrusion 801a of one interlayer insulating layer 401 in the vertical direction VD.

In an embodiment, the length of each of the plurality of word line contacts 820 in the vertical direction VD may be the same as the length of the cell plug 300 in the vertical direction VD. The lengths of the plurality of word line contacts 820 in the vertical direction VD may be the same as each other.

In an embodiment, the upper surfaces of the plurality of word line contacts 820 may be located at a higher level in the vertical direction VD than the upper surface of the uppermost layer of the stack structure ST. The upper surface of each of the plurality of word line contacts 820 may be located at the same level as the upper surface of the cell plug 300.

In an embodiment, the lower surfaces of the plurality of word line contacts 820 may be located at a lower level in the vertical direction VD than the lower surface of the lowermost layer of the stack structure ST. In an embodiment, the lower surface of each of the plurality of word line contacts 820 may be located at the same level as the lower surface of the cell plug 300.

The through contact 330 passes through the third insulating layer 408 and the fourth insulating layer 409 in the vertical direction VD. The through contact 330 includes a lower through contact 830a and an upper through contact 830b on the lower through contact 830a.

One word line contact 820 is electrically connected to the first transistor TR-PASS through one second wiring 807, one first bonding pad 805 and one second bonding pad 806 corresponding to the one second wiring 807.

One cell plug 300 is electrically connected to the second transistor TR-PB through one first wiring 407, one first bonding pad 805 and one second bonding pad 806 corresponding to the one first wiring 407.

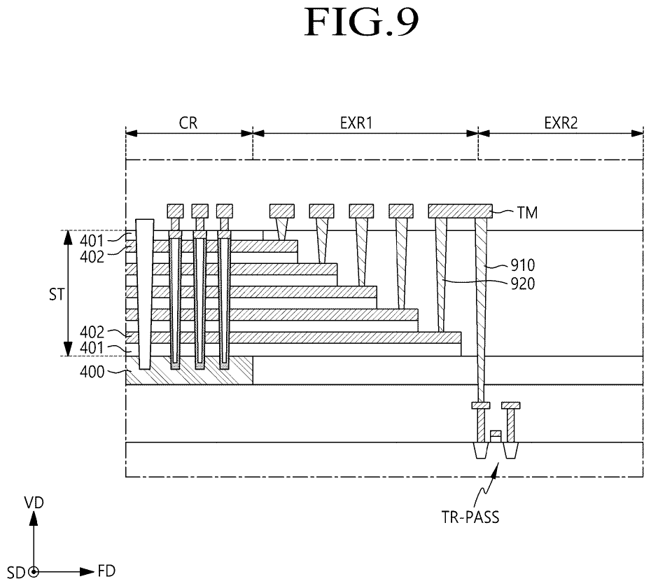

FIG. 9 is a view illustrating a cross-sectional structure of a memory device, which is different from the memory device according to the embodiments of the present disclosure.

Referring to FIG. 9, a stack structure ST may include a stairway structure in a first extended region EXR1. The stairway structure may be formed by a trimming process. The stairway structure includes step surfaces on which sections of the upper surfaces of a plurality of electrode layers 402 are respectively exposed.

Each of the step surfaces of the plurality of electrode layers 402 is connected to one word line contact 920. Each of word line contacts 920 is connected to a top electrode TM in a direction different from a direction in which the word line contact 920 is connected to the step surface. The top electrode TM extends to a second extended region EXR2. A contact 910 is disposed to connect the top electrode TM and a first transistor TR-PASS in the second extended region EXR2.

The plurality of electrode layers 402 are disposed at different locations, respectively, in the vertical direction VD. Each electrode layer 402 is connected to a corresponding word line contact 920 through a step surface. In order to connect the electrode layer 402 and the word line contact 920, the stack structure ST should have the stairway structure which includes the plurality of step surfaces.

In addition, the word line contact 920 is connected to the first transistor TR-PASS through the top electrode TM and the contact 910. Namely, in order to connect the word line contact 920 and the first transistor TR-PASS, more space for disposing a wiring or an electrode layer is required, which increases the size of the memory device.

Moreover, because the plurality of electrode layers 402 are disposed at different locations in the vertical direction VD, the length of the word line contact 920 connected to each electrode layer 402 varies, and thus, there is a high probability that a defect is likely to occur in the course of forming the word line contact 920.

Referring again to FIG. 4, the memory device 100 according to the embodiments of the present disclosure includes the stack structure ST, and each of the plurality of electrode layers 402 included in the stack structure ST includes the protrusion 402a which protrudes in the second direction SD. The protrusions 402a included in the plurality of electrode layers 402, respectively, do not overlap each other in the vertical direction VD. One word line contact 320 passes through only the protrusion 402a of a corresponding electrode layer 402.

According to the embodiments of the present disclosure, each word line contact 320 is connected to only one electrode layer 402. That is, even though the stack structure ST does not have a stairway structure, each of the plurality of electrode layers 402 may be connected to one word line contact 320. Therefore, the manufacturing process of the memory device 100 may be simplified.

In addition, according to the embodiments of the present disclosure, the word line contact 320 may be formed in the same shape at the same step as the cell plug 300. There is no need to differently set the lengths of the word line contacts 320 for the respective electrode layers 402. Therefore, it is possible to prevent a defect from occurring in the course of forming the word line contacts 320.

Referring again to FIG. 7, the memory device 100 according to the embodiments of the present disclosure includes the word line contact 720 which is connected to the first transistor TR-PASS by passing through the stack structure ST and the fourth insulating layer 409.

According to the embodiments of the present disclosure, because the word line contact 720 may be directly connected to the first transistor TR-PASS through the bottom electrode UM connected to the lower surface of the word line contact 720, compared to a case where the word line contact 720 and the first transistor TR-PASS are connected by disposing a conductive contact, a wiring or an electrode on the upper surface of the word line contact 720, a free space for wiring may be secured in the memory device 100, and the size of the memory device 100 may be reduced.

While the detailed embodiments of the present disclosure are disclosed, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes to the embodiments of the present disclosure within the meaning and range of equivalency of the claims are included within their scope. Furthermore, the embodiments may be combined to form additional embodiments.

What is claimed is:

1. A memory device comprising:
a first substrate including a cell region and an extended region which extends from the cell region in a first direction;
a stack structure including a plurality of interlayer insulating layers and a plurality of electrode layers which are alternately stacked on the first substrate, each of the plurality of electrode layers including a protrusion which protrudes in the extended region in a second direction that is perpendicular to the first direction and is parallel to an upper surface of the first substrate; and
a word line contact disposed in the extended region and passing through the protrusion of each of the plurality of electrode layers in a vertical direction.

2. The memory device according to claim 1, wherein the plurality of electrode layers includes a first electrode layer and a second electrode layer, and
the protrusion of the first electrode layer and the protrusion of the second electrode layer do not overlap each other in the vertical direction.

3. The memory device according to claim 2, wherein
the first electrode layer is disposed on the second electrode layer, and
the protrusion of the first electrode layer is closer to the cell region in the first direction than the protrusion of the second electrode layer.

4. The memory device according to claim 1, wherein the plurality of electrode layers includes a first electrode layer and a second electrode layer, and
the length of the protrusion of the first electrode layer in the second direction is substantially the same as the length of the protrusion of the second electrode layer in the second direction.

5. The memory device according to claim 1, wherein each of the plurality of electrode layers further includes an extension which is connected to the protrusion and extends to the extended region in the first direction.

6. The memory device according to claim 5, wherein the plurality of electrode layers includes a first electrode layer and a second electrode layer, and
the length of the extension of the first electrode layer in the first direction is substantially the same as the length of the extension of the second electrode layer in the first direction.

7. The memory device according to claim 1, wherein the protrusion of each of the plurality of electrode layers corresponds one-to-one to the word line contact.

8. The memory device according to claim 1, wherein each of the plurality of electrode layers is electrically connected to the word line contact through the protrusion through which the word line contact passes.

9. The memory device according to claim 1, wherein
the plurality of electrode layers includes a first electrode layer and a second electrode layer,
the word line contact includes a first word line contact which passes through the protrusion of the first electrode layer and a second word line contact which passes through the protrusion of the second electrode layer, and
the length of the first word line contact in the vertical direction is substantially the same as the length of the second word line contact in the vertical direction.

10. The memory device according to claim 1, further comprising:
a cell plug disposed in the cell region and passing through the stack structure in the vertical direction,
wherein the length of the cell plug in the vertical direction is substantially the same as the length of the word line contact in the vertical direction.

11. The memory device according to claim 1, further comprising:
a pass transistor disposed below the first substrate,
wherein the word line contact connects the protrusion and the pass transistor.

12. The memory device according to claim 11, further comprising:
a cell plug disposed in the cell region and passing through the stack structure in the vertical direction,
wherein the length of the word line contact in the vertical direction is greater than the length of the cell plug in the vertical direction.

13. The memory device according to claim 1, further comprising:
a first wafer including the stack structure and a first bonding insulating layer on the stack structure; and
a second wafer disposed on the first wafer and including a second bonding insulating layer which contacts one surface of the first bonding insulating layer.

14. A memory device comprising:
a first substrate;
a stack structure including a plurality of interlayer insulating layers and a plurality of electrode layers which are alternately stacked on the first substrate, each of the plurality of electrode layers including a protrusion which does not overlap the other electrode layers in a vertical direction and protrudes in a direction parallel to an upper surface of the first substrate; and
a word line contact passing through the protrusion of each of the plurality of electrode layers in the vertical direction.

15. The memory device according to claim 14, wherein the protrusion contacts a side surface of the word line contact.

16. The memory device according to claim 14, wherein each of the plurality of electrode layers is connected to the word line contact through the protrusion.

17. The memory device according to claim 14, wherein protrusions of the plurality of electrode layers overlap each other in a direction parallel to the upper surface of the first substrate and perpendicular to the direction in which the protrusions protrude.

18. A memory device comprising:
a substrate including a cell region and an extended region which extends from the cell region in a first direction;
a stack structure including a plurality of interlayer insulating layers and a plurality of electrode layers which are alternately stacked on the substrate;
a cell plug passing through the stack structure in a vertical direction in the cell region; and
a word line contact passing through one electrode layer among the plurality of electrode layers in the vertical direction in the extended region.

19. The memory device according to claim 18, wherein the word line contact does not overlap the other electrode layers except the one electrode layer in the vertical direction.

20. The memory device according to claim 18, wherein the diameter of the cell plug is substantially the same as the diameter of the word line contact.
